(19) United States
(12) Patent Application Publication
(10) Pub. No.: US 2010/0282304 A1
(43) Pub. Date: Nov. 11, 2010

(54) SOLAR CELL AND METHOD OF MANUFACTURING THE SAME

(75) Inventors: Ming-Hsien Wu, Tainan County (TW); Wen-Yung Yeh, Hsinchu County (TW); Rong Xuan, Taipei County (TW); Wen-Yih Liao, Taichung City (TW); Jung-Tsung Hsu, Hsinchu City (TW); Mu-Tao Chu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/273,501

(22) Filed: Nov. 18, 2008

(51) Int. Cl. H01L 31/0256; H01L 31/00; H01L 31/02; H01L 31/18

(52) U.S. Cl. 136/254; 136/252; 136/261; 136/262; 136/256; 438/93; 257/E31.032; 257/E31.019

(57) ABSTRACT

A bi-functional photovoltaic device is provided. The bi-functional photovoltaic device includes at least one solar cell and a control device. Each of the solar cell includes a multilayer semiconductor layer of group III-V compound semiconductor, a first electrode disposed on the back of the multilayer semiconductor layer, and a second electrode disposed on the front of the multilayer semiconductor layer. The control device connects with the at least one solar cell in order to control them functioning as solar cell or light emitting diode.

### BACKGROUND OF THE INVENTION

1. Field of Invention

The present invention relates to a solar cell for improving properties thereof.

2. Description of Related Art

The supply of fossil fuels faces the shortage problem, and the combustion of fossil fuels leads to the air pollution and environmental damage. Nuclear energy can provide high electricity density, but it has the safety concern about the radiation and the storage of nuclear waste. Both of the above-mentioned energy increases the social cost. Therefore, renewable energy becomes the focus in terms of energy saving and pollution reducing. Many nations have started to develop and invest in the renewable energy and the feasibility as alternative energy.

Photovoltaic (PV) modules of photoelectric conversion devices become the mainstream of alternative energy. Solar cells (or photovoltaic cells) which can convert solar energy directly into electricity are under intensive study. Solar energy is clean and inexhaustible with few limitations. Electric power can be generated as long as sunlight exists. Recently, many kinds of solar cell are developed to improve various properties.

Conventional solar powered solid state lighting (SSL) system needs at least two components. One of the components is a photovoltaic device, and the other is a solid-state lighting device. In general, the solar powered solid state lighting system is formed with a light emitting diode and a solar cell. However, the foregoing system may undergo cost issue and have system dimension problem which will limit the development of the system.

In GaN-based system, most of the devices are fabrication in lateral structure due to the sapphire substrate, which has low conductivity, low thermal resistance and large lattice mismatch with epi-layer. Besides, lateral structure devices need more area to fabricate devices with the same absorption area compared to vertical ones. For photovoltaic system, photogenerated carriers need to be collected by two electrodes, which are disposed on different conduction-type portions of the multilayer semiconductor. In order to improve the lateral carrier transportation on the surface, a transparent contact layer (TCL) is usually needed. However, the light incident rate is reduced due to surface light absorption of the TCL.

In order to absorb more incident light, a thicker absorption layer is usually taken into consideration. However, the increase of the absorption thickness means higher cost and heavy device.

In addition, the photogenerated carriers in conventional PV modules is collected by forked electrodes on a surface of the multilayer semiconductor through a lateral transmission. Due to relatively low carrier concentration of the surface of the multilayer semiconductor, the photogenerated carriers may be trapped or recombined therein during the lateral transmission. Thus, the opto-electric conversion efficiency is also reduced.

### SUMMARY OF THE INVENTION

The present invention provides a solar cell with photonic crystals so as to enhance the photoelectric performance of the solar cell.

The present invention also provides a GaN-based solar cell and a method of manufacturing the GaN-based solar cell. In accordance to the GaN-based solar cell of the present invention, the active layer thereof is sandwiched by positive electrode and negative electrode.

The present invention further provides a bi-functional photovoltaic device and a bi-functional apparatus utilizing the same.

A solar cell is provided. The solar cell includes a substrate having a surface with a first kind of photonic crystals, a multilayer semiconductor layer having at least one active layer, a first electrode and a second electrode. The multilayer semiconductor layer is disposed on the surface of the substrate, and a second kind of photonic crystals is disposed on a top surface of the semiconductor layer. The first electrode and the second electrode are respectively disposed on different conduction-type portions of the multilayer semiconductor layer's two terminals for forming ohmic contacts.

A GaN-based solar cell is provided. The GaN-based solar cell includes a first electrode, a second electrode, and a multilayer semiconductor layer having at least one active layer. A material of the multilayer semiconductor layer is a GaN-based semiconductor or alloy thereof. The first electrode is disposed on a surface of the first conductive type semiconductor, and the second electrode is disposed on a surface of the second conductive type semiconductor opposite to the first electrode.

A method of fabricating a GaN-based solar cell is further provided. First, a sapphire substrate is provided, and then a multilayer semiconductor layer is formed on the sapphire substrate, wherein a material of the multilayer semiconductor layer is a GaN-based semiconductor. Thereafter, a conductive connected layer and a metal layer are formed on the multilayer semiconductor layer in order. Then, the sapphire substrate is totally or partially removed, and then an electrode is foamed on a surface of the multilayer semiconductor layer where the sapphire substrate is removed.

A bi-functional photovoltaic device is provided that includes at least one solar cell and a control device. Each of the solar cell includes a multilayer semiconductor layer of group III-V compound having at least one active layer, a first electrode disposed on the back of the multilayer semiconductor layer with a first kind of conduction type, and a second electrode disposed on the front of the multilayer semiconductor layer with a second kind of conduction type opposite to a back of the multilayer semiconductor layer. The control device connects with the at least one solar cell in order to control the at least one solar cell functioning as solar cell or light emitting diode.

A bi-functional apparatus is also provided. The bi-functional apparatus includes a pedestal, a carrier with circuit layout, the foregoing bi-functional photovoltaic device, a condensing-lens hood, and a storage battery. The carrier is disposed on the pedestal, and the bi-functional photovoltaic device is disposed on the carrier. Moreover, the condensing-lens hood is assembled with the pedestal for hooding the bi-functional photovoltaic device, and the storage battery is disposed on the pedestal for store of electricity from the at least one solar cell of the bi-functional photovoltaic device.

A photovoltaic module is also provided. The photovoltaic module includes a photovoltaic device, a N- and a P-type contacts and an applied energy field. The photovoltaic device includes at least one of p-n and a p-i-n structures in order to generate a plurality of photogenerated carriers when being irradiated, and it has a N- and a P-conduction type surfaces. The N-type and a P-type contacts are on the N- and the P-conduction type surfaces of the photovoltaic device, respectively. The applied energy field is near the photovoltaic device to chance a moving directions of a flow of the plurality of photogenerated carriers in the photovoltaic device, such that a photocurrent of the photovoltaic device is increased.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a solar cell of a first embodiment of the present invention.

FIG. 2 is a schematic diagram of a solar cell of a second embodiment of the present invention.

FIG. 3 is a schematic diagram of a GaN-based solar cell of a third embodiment of the present invention.

FIGS. 4A-4D are flow diagrams showing the steps for manufacturing a GaN-based solar cell of a fourth embodiment of the present invention.

FIGS. 5A-5D are flow diagrams showing the steps for manufacturing a GaN-based solar cell of a fifth embodiment of the present invention.

FIG. 6 is a block diagram of a bi-functional photovoltaic device of a sixth embodiment of the present invention.

FIGS. 7A and 7B are schematic diagrams showing the two kinds of solar cells in the bi-functional photovoltaic device of FIG. 6.

FIG. 8 is a perspective diagram of a bi-functional apparatus of a seventh embodiment of the present invention.

FIG. 9 is a schematic diagram of a photovoltaic module of a eighth embodiment of the present invention.

FIGS. 10A-10C are flow diagrams showing the steps for manufacturing a photovoltaic module of the eighth embodiment of the present invention.

### DESCRIPTION OF EMBODIMENTS

A schematic diagram of a solar cell of a first embodiment of the present invention is shown in FIG. 1. The solar cell is group III-V compound solar cell, for example. FIG. 1 shows a lateral view of the solar cell 10, which includes a substrate 100 having a surface 100a with photonic crystals 102, a multilayer semiconductor layer 110, a first electrode 112a and a second electrode 112b. The substrate 100 includes sapphire, GaAs, Ge, Si, SiGe or the other materials, for example. The multilayer semiconductor layer 110 is disposed on the surface 100a of the substrate 100, and the first electrode 112a and the second electrode 112b are respectively disposed on different conduction-type portions of the multilayer semiconductor layer 110. For example, an arrangement of the photonic crystals 102 includes periodic, quasi-periodic or non-periodic arrangement, in which the periodic arrangement may include four-fold rotational symmetry or six-fold rotational symmetry. Moreover, the photonic crystals 102 may be produced by Laser interferometric lithography, electron beam lithography or Nanoimprint.

In the first embodiment, the multilayer semiconductor layer 110 includes a n-type semiconductor layer 104, at least one active layer 106 and a p-type semiconductor layer 108 as shown in FIG. 1. Thus, the first electrode 112a is disposed on the p-type semiconductor layer 108, and the second electrode 112b is disposed on the n-type semiconductor layer 104, for example. In addition, a material of the substrate 100 includes Sapphire, SiC, Si, GaAs or AlN, for example. A type of the first electrode 112a and the second electrode 112b include forked, concentric or circular type, for example. In another embodiment, a material of the multilayer semiconductor layer 110 includes a group II-VI compound semiconductor. If need be, a top anti-reflective coating (not shown) and a back surface reflection electrode (not shown) may be disposed in the solar cell 10 of the first embodiment, independently. In addition, the solar cell 10 of the first embodiment may be a single junction structure, a multi junction structure or a mechanically-laminated structure, for example.

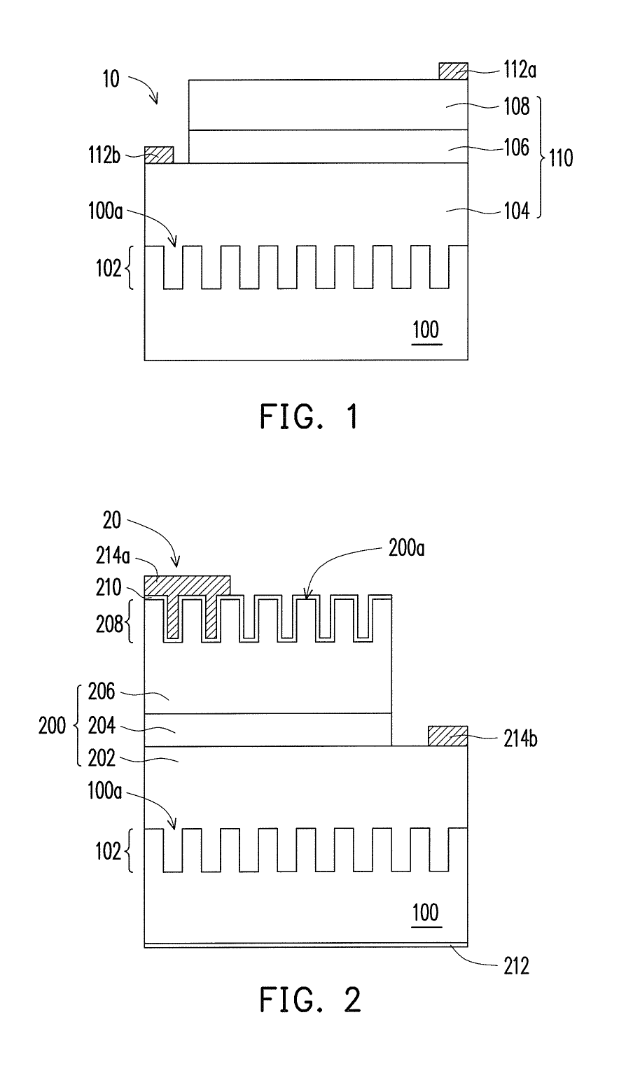

For further explanation, a schematic diagram of a solar cell of a second embodiment of the present invention is shown in FIG. 2. FIG. 2 shows a solar cell 20 similar to that in FIG. 1, and the same numbers represent the same elements in FIGS. 1 and 2. The solar cell 20 includes a substrate 100 having a surface 100a with photonic crystals 102 and a multilayer semiconductor layer 200, wherein the multilayer semiconductor layer 200 has a top surface 200a with other photonic crystals 208. In addition, an arrangement of the photonic crystals 208 includes periodic, quasi-periodic or non-periodic arrangement, in which the periodic arrangement may include four-fold rotational symmetry or six-fold rotational symmetry. Moreover, the photonic crystals 208 may be produced by Laser interferometric lithography, electron beam lithography or Nanoimprint. When a light is incident to the solar cell 20 from the top surface 200a with first kind photonic crystal 102 functioned as surface texture surface, the light may exceed its light output cone through diffraction from the influence of the photonic crystals 102 of the substrate 100, and thus the light penetrated the substrate 100 will be reflected to the inner of the solar cell 20 and the reflection of incident light will be reduced. The influence of the photonic crystals 208 is also to reflect the light which not be absorbed in the absorption layer of solar cell. When the light reflected back to the top surface 200a, the first photonic crystal 102 can also reflect the incident light again by means of the diffraction. Therefore, the absorption probability of the light in the solar cell 20 can be increased, whereby improving the efficiency of the solar cell 20. In addition, the absorption probability of the light in the solar cell 20 is larger, the desired thickness of an absorption layer in the solar cell is thinner. Therefore, the advantage of the thinner thickness is not only less cost and lighter weight, but also the prevention of defect caused by mismatch of lattice constant in the growth of heterojunction.

In the second embodiment, the multilayer semiconductor layer 200 includes a n-type semiconductor layer 202, at least one active layer 204 and a p-type semiconductor layer 206, and it may be a p-n or a p-i-n structure. Moreover, a top anti-reflective coating 210 may be disposed on the top surface 200a of the multilayer semiconductor layer 200, and a back surface reflection electrode 212 may be disposed on the back of the substrate 100, if necessary. Besides, the solar cell 20 of the second embodiment may be a single junction structure, a multi junction structure or a mechanically-stacked structure, for example. Furthermore, the first electrode 214a and the second electrode 214b in FIG. 2 are disposed on different conduction-type portions (i.e. the n-type semiconductor layer 202 and the p-type semiconductor layer 206) of two terminals of the multilayer semiconductor layer 200.

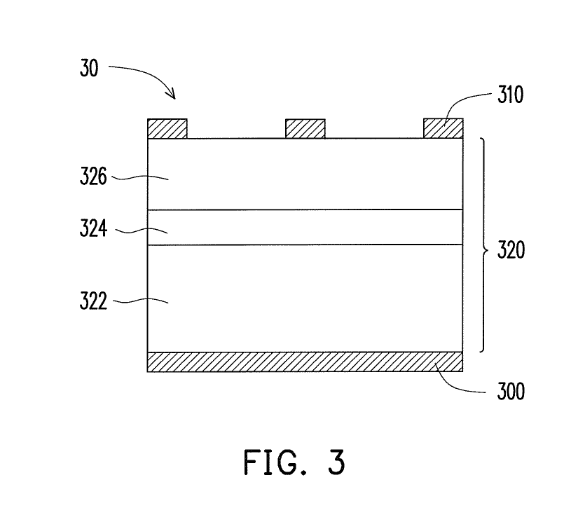

A schematic diagram of a GaN-based solar cell of a third embodiment of the present invention is shown in FIG. 3. FIG. 3 shows a GaN-based solar cell 30 that includes a first electrode 300, a second electrode 310, and a multilayer semiconductor layer 320 having at least one active layer 324, wherein a material of the multilayer semiconductor layer 320 is a GaN-based semiconductor or alloy thereof, such as GaN, InN, AlN, InGaN, AlGaN, AlInGaN and so on. In FIG. 3, the multilayer semiconductor layer 320 includes a first conductive type semiconductor 322, the active layer 324, and a second conductive type semiconductor 326, for example. The first electrode 300 is disposed on a surface of the first conductive type semiconductor 322, and the second electrode 310 is disposed on a surface of the second conductive type semiconductor 326 opposite to the first electrode 300. Furthermore, the multilayer semiconductor layer 320 includes a p-n or a p-i-n structure. A type of the first electrode 300 and the second electrode 310 includes forked, concentric or circular type, for example. In FIG. 3, the first conductive type semiconductor 322 may be a N-type semiconductor, and the second conductive type semiconductor 326 may be a P-type semiconductor.

Several embodiments are provided below as examples of manufacturing the GaN-based solar cell according the third embodiment.

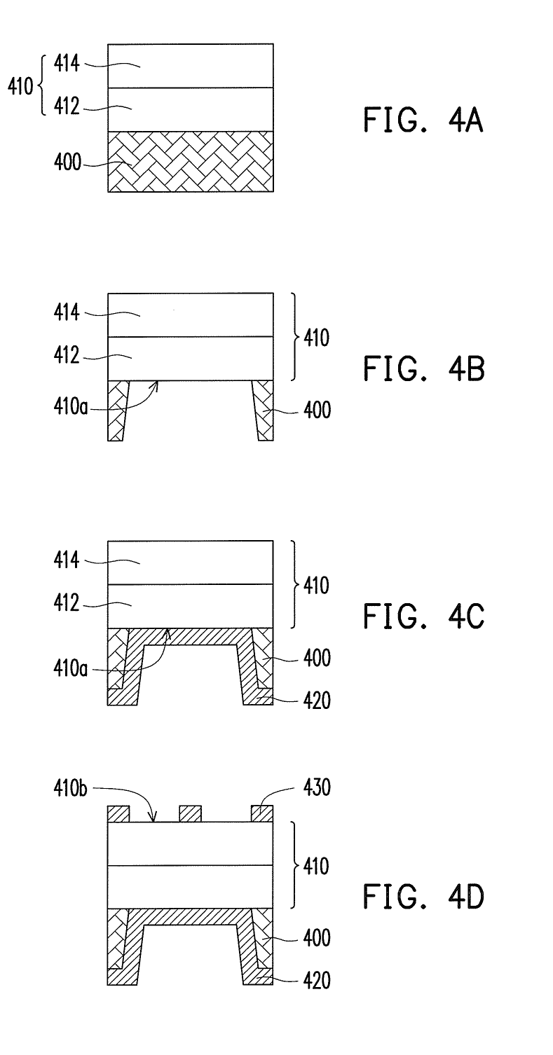

FIGS. 4A-4D are schematic cross-sectional views illustrating a process flow for manufacturing a GaN-based solar cell of a fourth embodiment of the present invention.

Please refer to FIG. 4A at first. A sapphire substrate 400 is provided, and a multilayer semiconductor layer 410 is then formed on the sapphire substrate 400, wherein a material of the multilayer semiconductor layer 410 is a GaN-based semiconductor, such as GaN, InN, AlN, InGaN, AlGaN, AlInGaN, etc. In FIG. 4A, the step of forming the multilayer semiconductor layer 410 includes a step of forming a N-type layer 412 and a step of forming a P-type layer 414 thereon, for example.

Next, referring to FIG. 4B, a portion of the sapphire substrate 400 is removed to expose a back 410a of the multilayer semiconductor layer 410, wherein the method of removing the portion of the sapphire substrate 400 includes dry etching or wet etching so as to expose the N-type layer 412.

After that, referring to FIG. 4C, a first electrode 420 is formed on the back 410a of the multilayer semiconductor layer 410.

Afterwards, referring to FIG. 4D, a second electrode 430 is formed on the front 410b of the multilayer semiconductor layer 410. For example, a type of the second electrode 430 may be forked, concentric or circular type.

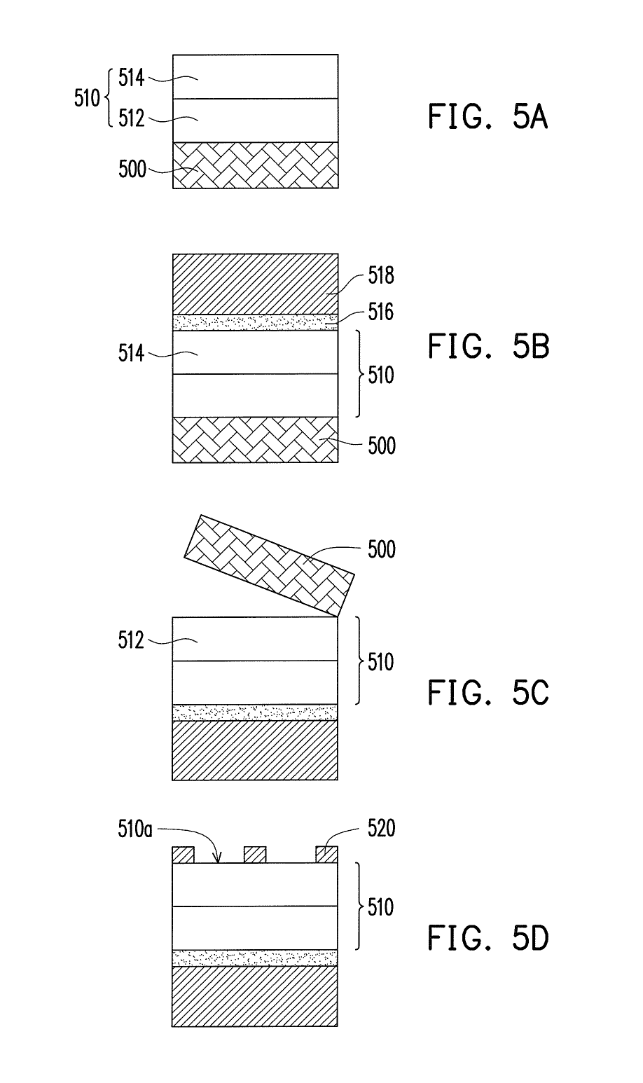

FIGS. 5A-5D are schematic cross-sectional views illustrating a process flow for manufacturing a GaN-based solar cell of a fifth embodiment of the present invention.

Please refer to FIG. 5A. A sapphire substrate 500 is provided, and a multilayer semiconductor layer 510 is then formed on the sapphire substrate 500, wherein a material of the multilayer semiconductor layer 510 is a GaN-based semiconductor, such as GaN, InN, AlN, InGaN, AlGaN, AlInGaN, etc. In FIG. 5A, the step of forming the multilayer semiconductor layer 510 includes a step of forming a N-type layer 512 and a step of forming a P-type layer 514 thereon, for example.

Next, referring to FIG. 5B, a conductive connected layer 516 is formed on the multilayer semiconductor layer 510 and touches the P-type layer 514, and a metal layer 518 is then formed on the conductive connected layer 516.

Afterwards, referring to FIG. 5C, the sapphire substrate 500 is removed. The method of removing the portion of the sapphire substrate 500 includes dry etching, wet etching, Laser lift-off or self-separation technique, for example. At the time, the N-type layer 512 of the multilayer semiconductor layer 510 is exposed.

After that, referring to FIG. 5D, a electrode 520 is formed on a surface 510a of the multilayer semiconductor layer 510 where the sapphire substrate (referring to 500 of FIG. 5C) is removed.

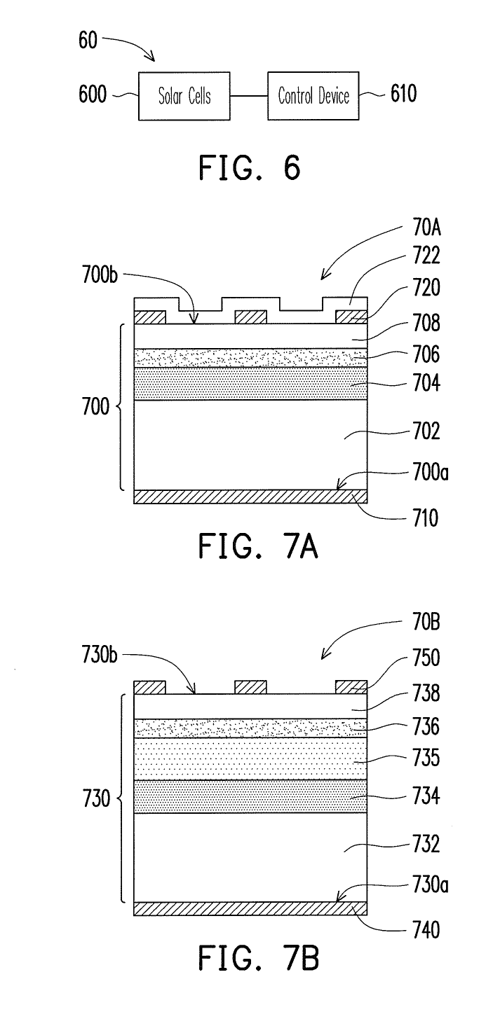

FIG. 6 is a block diagram of a bi-functional photovoltaic device of a sixth embodiment of the present invention. The bi-functional photovoltaic device 60 includes at least one solar cell 600 and a control device 610 as shown in FIG. 6. The at least one solar cell 600 is connected to the control device 610, and consequently the control device 610 may control the solar cells 600 functioning as solar cell or light emitting diode. The solar cells are a single-junction structure or a multi junction structure, for example. Moreover, the control device 610 may be a timer, photosensor or current meter, for example. In the bi-functional photovoltaic device 60, it is possible to use a timer for determining the operation conditions of different function. For example, the sunshine from morning till afternoon is more than that in the evening, so the bi-functional photovoltaic device 60 is used as a solar cell before evening but as a solid state lighting (SSL) in the evening. In other words, the operation conditions of different function can be determined by the timer according to different time. In addition, if the control device 610 is a photosensor, it is possible to actively determine the operation conditions; for instance, when the photosensor receives a light more than a desired value, it means that environmental light is enough to determine the bi-functional photovoltaic device 60 being used as a solar cell, and when the photosensor receives a light less than the desired value, it means that environmental light is not enough, and thus the bi-functional photovoltaic device 60 is determined to be a SSL. Except for the utilization of the photosensor, a photocurrent generated from the solar cells 600 is also used to directly decide the environmental situation. For example, when the photocurrent in the solar cells 600 is greater than a desired value, it means that environmental light is enough to make the bi-functional photovoltaic device 60 being used as a solar cell; on the contrary, the bi-functional photovoltaic device 60 is used as a SSL.

FIGS. 7A and 7B are schematic diagrams showing the two kinds of solar cells in the bi-functional photovoltaic device of FIG. 6. FIG. 7A shows a solar cell 70A which includes a multilayer semiconductor layer of group III-V compound 700, a first electrode 710, and a second electrode 720. The first electrode 710 is disposed on the back 700a of the multilayer semiconductor layer 700 with a first kind of conduction type, and the multilayer semiconductor layer 700 may be a back surface field (BSF) layer, for example. The second electrode 720 is disposed on the front 700b of the multilayer semiconductor layer 700 with a second kind of conduction type opposite to the back 700a. In addition, the front 700b of the multilayer semiconductor layer 700 may has textured surface optionally. In FIG. 7A, the multilayer semiconductor layer 700 includes a P-layer 702, a P-depletion layer 704, a N-depletion layer 706, and a N-layer 708 arranged from the first electrode 710 to the second electrode 720, and thus the first kind of conduction type is P-type and the second kind of conduction type is N-type in the sixth embodiment. An anti-reflective coating 722 may be disposed on the front 700b of the multilayer semiconductor layer 700, if necessary.

FIG. 7B shows a solar cell 70B. The solar cell 70B includes a multilayer semiconductor layer of group III-V compound 730, a first electrode 740, and a second electrode 750. The first electrode 740 is disposed on the back 730a of the multilayer semiconductor layer 730 with a first kind of conduction type, and the second electrode 750 is disposed on the front 730b of the multilayer semiconductor layer 730 with a second kind of conduction type opposite to the back 730a. In FIG. 7B, the multilayer semiconductor layer 730 includes a P-layer 732, a P-depletion layer 734, an intrinsic layer (I-layer) 735, a N-depletion layer 736, and a N-layer 738 arranged from the first electrode 740 to the second electrode 750, and thus the first kind of conduction type is P-type and the second kind of conduction type is N-type in FIG. 7B. Furthermore, the various modifications and variations can refer to the related descriptions of FIG. 7A.

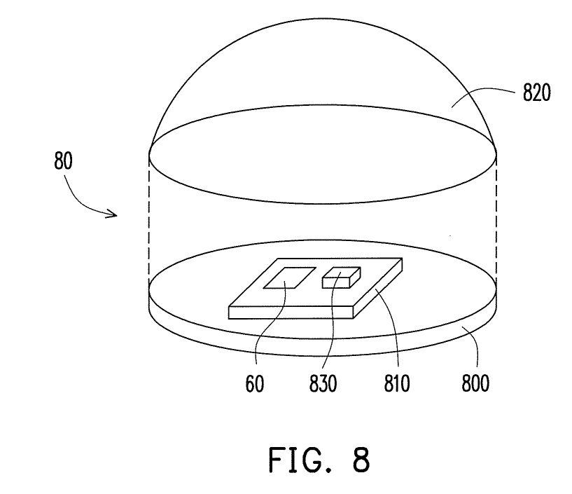

A perspective diagram of a bi-functional apparatus of a seventh embodiment of the present invention is shown in FIG. 8. The same numbers represent the same device in FIG. 6 and FIG. 8. FIG. 8 shows a bi-functional apparatus 80. The bi-functional apparatus 80 includes a pedestal 800, a carrier 810 with circuit layout, the bi-functional photovoltaic device 60, a condensing-lens hood 820, and a storage battery 830. The carrier 810 is disposed on the pedestal 800, and the bi-functional photovoltaic device 60 is disposed on the carrier 810. Moreover, the condensing-lens hood 820 is assembled with the pedestal 800 for hooding the bi-functional photovoltaic device 60. And, the storage battery is disposed on the pedestal 800 so as to store electricity from the solar cells of the bi-functional photovoltaic device 60.

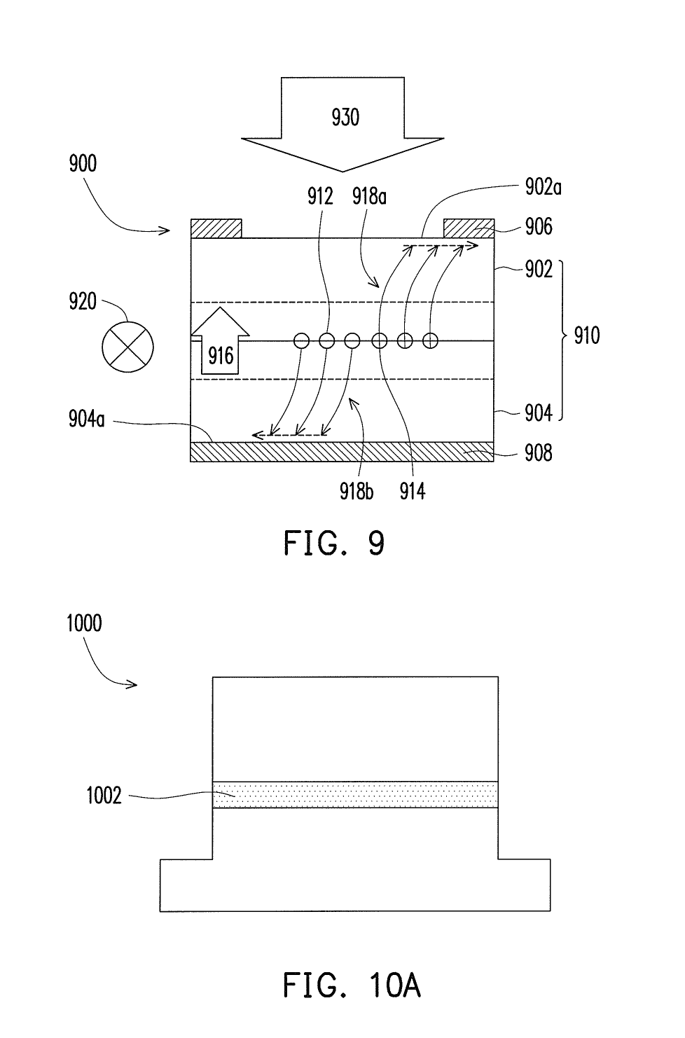

FIG. 9 is a schematic diagram of a photovoltaic module of a eighth embodiment of the present invention.

Please refer to FIG. 9, the photovoltaic module 900 includes a photovoltaic device 910 and an applied energy field 920. The photovoltaic device 910 includes at least one p-n structure consisting of a P-layer 902 with a P-conduction type surface 902a and a N-layer 904 with a N-conduction type surface 904a. The photovoltaic device 910 may include at least one p-i-n structure except for FIG. 9. In addition, the photovoltaic device 910 further includes a P-type electrode 906 and a N-type electrode 908 on the P- and N-conduction type surfaces 902a and 904a of the photovoltaic device 910, respectively. When the photovoltaic device 910 is irradiated by light 930, electrons 912 and holes 914 (i.e. photogenerated carriers) are generated. The applied energy field 920 is near the photovoltaic device 910, wherein the applied energy field 920 may be magnetic field or electric field, for example. In this embodiment, the applied energy field 920 is a magnetic field, and a field direction of the magnetic field is perpendicular to the paper and point to it. The magnetic field may be induced by live long straight wire, spiral coil, or circular loop, or the magnetic field may be produced from a magnetizing material, for example. If the applied energy field 920 is an electric field, it may be time-varying field or time-invariant field. If the applied energy field 920 is a magnetic field, it may be time-varying field or time-invariant field.

Please refer to FIG. 9 again, when a current direction 916 of photocurrents of the photovoltaic device 910 is from the P-layer 904 to the N-layer 902 and the field direction of the magnetic field (i.e. the applied energy field 920) is not parallel to the current direction 916, a plurality of moving directions 918a-b of a flow of the electrons 912 and holes 914 will be changed. In FIG. 9, the field direction of the applied energy field 920 is perpendicular to the paper. The electrons 912 are induced to the N-type electrode 908 and the holes 914 are induced to the P-type electrode 906 by the resulting from the magnetic field. Therefore, an included angle of the moving direction 918a of the holes 914 and the field direction of the magnetic field (i.e. the applied energy field 920) is more than 0° and less than 180°. Similarly, an included angle of the moving direction 918b of the electrons 912 and the field direction of the magnetic field is more than 0° and less than 180°.

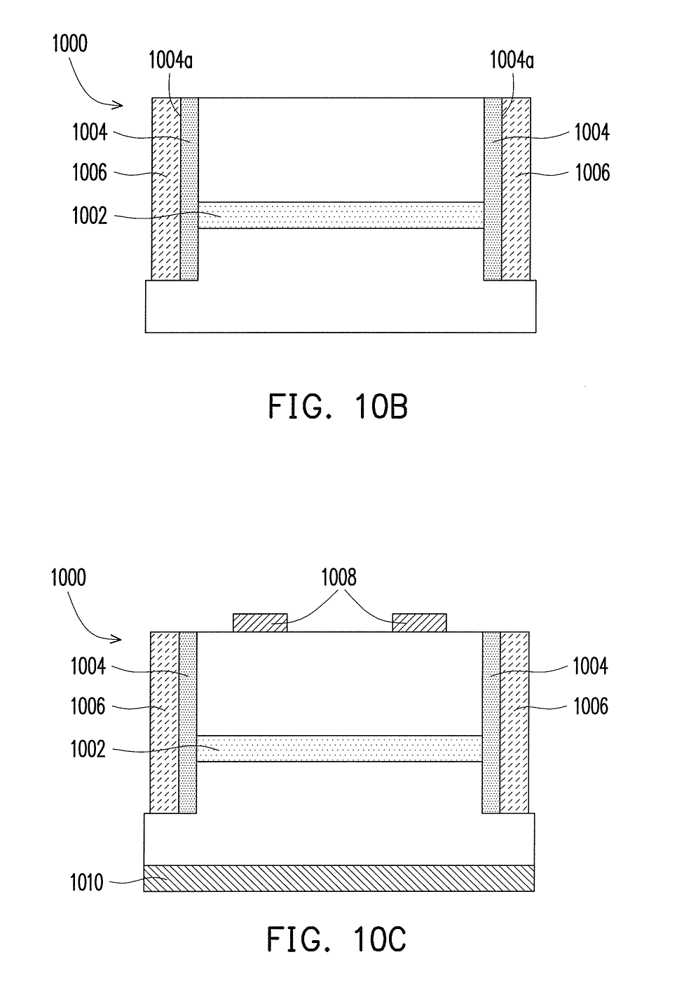

FIGS. 10A-10C are schematic cross-sectional views illustrating a process flow for manufacturing a photovoltaic module of the eighth embodiment of the present invention.

Please refer to FIG. 10A. A photovoltaic device 1000 with an active layer 1002 is provided and a portion of the photovoltaic device 1000 is then removed to expose at least one side of the active layer 1002.

Next, referring to FIG. 10B, an isolation layer 1004 is formed around the active layer 1002 and extended to cover sidewalls 1000a of the photovoltaic device 1000. Afterwards, an applied energy field 1006 such as magnetizing material is formed on an external side 1004a of the isolation layer 1004.

After that, referring to FIG. 10C, a front electrode 1008 and a back electrode 1010 are formed on the front and back of the photovoltaic device 1000 respectively.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell, comprising:
a substrate having a surface with a first kind of photonic crystals;
a multilayer semiconductor layer, disposed on the surface of the substrate, wherein the multilayer semiconductor layer has at least one active layer;
a second kind of photonic crystals on a top surface of the semiconductor layer; and
a first electrode and a second electrode, respectively disposed on different conduction-type portions of the multilayer semiconductor layer's two terminals for forming ohmic contacts.

2. The solar cell according to claim 1, wherein the multilayer semiconductor layer comprises a p-n or a p-i-n structure.

3. The solar cell according to claim 1, wherein an arrangement of the photonic crystals comprises periodic, quasi-periodic or non-periodic arrangement.

4. The solar cell according to claim 3, wherein the periodic arrangement comprises four-fold rotational symmetry or six-fold rotational symmetry.

5. The solar cell according to claim 1, wherein the substrate comprises sapphire, GaAs, Ge, Si or SiGe.

6. A GaN-based solar cell, comprising:
a multilayer semiconductor layer having at least one active layer, wherein a material of the multilayer semiconductor layer is a GaN-based semiconductor or alloy thereof;
a first electrode disposed on a surface of the first conductive type semiconductor; and
a second electrode disposed on a surface of the second conductive type semiconductor opposite to the first electrode.

7. The GaN-based solar cell according to claim 6, wherein the multilayer semiconductor layer comprises a p-n or a p-i-n structure.

8. The GaN-based solar cell according to claim 6, wherein a type of the first electrode and the second electrode comprises forked, concentric or circular type.

9. The GaN-based solar cell according to claim 6, further comprises a sapphire substrate sandwiched by the first electrode and the multilayer semiconductor layer; and a portion of the sapphire substrate is removed to let the multilayer semiconductor layer and the first electrode contact.

10. A bi-functional photovoltaic device, comprising:
at least one solar cell, wherein each of the solar cell comprising:
a multilayer semiconductor layer of group III-V compound having at least one active layer, wherein the multilayer semiconductor layer has a front and a back;
a first electrode, disposed on the back of the multilayer semiconductor layer with a first kind of conduction type; and
a second electrode, disposed on the front of the multilayer semiconductor layer with a second kind of conduction type opposite to the back of the multilayer semiconductor layer; and
a control device, connecting with the at least one solar cells in order to control the at least one solar cell functioning as solar cell or light emitting diode.

11. The bi-functional photovoltaic device according to claim 10, wherein the active layer comprises a p-n or a p-i-n structure.

12. The bi-functional photovoltaic device according to claim 10, further comprising an anti-reflective coating or textured surface on the front of the multilayer semiconductor layer.

13. The bi-functional photovoltaic device according to claim 10, wherein the multilayer semiconductor comprise a back surface field (BSF) layer on the first electrode.

14. The bi-functional photovoltaic device according to claim 10, wherein the control device comprises a timer, photosensor or current meter.

15. A bi-functional apparatus, comprising:
a pedestal;
a carrier with circuit layout, disposed on the pedestal;
the bi-functional photovoltaic device according to claim 10, disposed on the carrier;
a condensing-lens hood, assembled with the pedestal for hooding the bi-functional photovoltaic device; and
a storage battery, disposed on the pedestal for storing electricity from the at least one solar cell of the bi-functional photovoltaic device.

16. A method of manufacturing a GaN-based solar cell, comprising:
providing a sapphire substrate;
forming a multilayer semiconductor layer on the sapphire substrate, wherein a material of the multilayer semiconductor layer is a GaN-based semiconductor;
forming a conductive connected layer on the multilayer semiconductor layer;
forming a metal layer on the conductive connected layer;
removing the sapphire substrate totally or partially; and
forming an electrode on a surface of the multilayer semiconductor layer where the sapphire substrate is removed.

17. The method according to claim 16, wherein the step of forming the multilayer semiconductor layer, comprising:
forming a N-type layer; and
forming a P-type layer on the N-type layer.

18. The method according, to claim 16, wherein the method of removing the portion of the sapphire substrate comprises dry etching, wet etching, Laser lift-off or self-separation technique.

19. A photovoltaic module, comprising:
a photovoltaic device, comprising at least one of p-n or p-i-n structures to generate a plurality of photogenerated carriers when being irradiated, wherein the photovoltaic device has a N- and a P-conduction type surfaces;
a N- and a P-type contacts, on the N- and P-conduction type surfaces of the photovoltaic device, respectively; and
an applied energy field, near the photovoltaic device to change a moving direction of a flow of the plurality of photogenerated carriers in the photovoltaic device, such that a photocurrent of the photovoltaic device is increased.

20. The photovoltaic module according to claim 19, wherein the applied energy field is a magnetic field or an electric field.

21. The photovoltaic module according to claim 20, wherein the electric field is time-varying field or time-invariant field, and the magnetic field is time-varying field or time-invariant field.

22. The photovoltaic module according to claim 20, wherein the magnetic field is induced by live long straight wire, spiral coil, or circular loop, or the magnetic field is produced from a magnetizing material.

23. The photovoltaic module according to claim 20, further comprising an isolation layer around the photovoltaic device, and the magnetic field is induced by a magnetizing material on an external side of the isolation layer.

24. The photovoltaic module according to claim 19, wherein a field direction of the applied energy field is not parallel to the current direction of the photocurrent of the photovoltaic device, and an included angle of the field direction of the applied energy field and the current direction is more than 0° and less than 180°.
